(19) United States
(12) Patent Application Publication
(10) Pub. No.: US 2007/0147010 A1
(43) Pub. Date: Jun. 28, 2007

(54) Drive slot shutters for drive enclosures

(76) Inventors: Roxanne Arnel, Wichita, KS (US); Sridhar Balasubramanian, Wichita, KS (US)

Correspondence Address: LSI LOGIC CORPORATION, 1621 BARBER LANE, MS: D-106, MILPITAS, CA, 95035, US

(21) Appl. No.: 11/315,913

(22) Filed: Dec. 22, 2005

(51) Int. Cl. H05K 7/16

(52) U.S. Cl. 361/727; 361/685

(57) ABSTRACT

A drive enclosure for a modular data storage system includes drive slots which include shutters for closing the drive slot when no drive is present in the slot. The shutter opens as a drive is received in the drive slot for allowing insertion of the drive within the drive slot and closes when the drive is removed from the drive slot.

### FIELD OF THE INVENTION

The present invention generally relates to drive enclosures used in modular data storage systems, and more particularly, to a drive enclosure having drive slots including mechanically-operated drive slot shutters for closing unused drive slots (i.e., drive slots which are unoccupied by a drive).

### BACKGROUND OF THE INVENTION

Modular data storage systems employ a cabinet or rack which supports a plurality of drive enclosures or modules, each including a plurality of data storage drives (e.g., Fibre Channel drives, serial ATA drives, or the like) controlled by one or more controllers. Typically, each drive enclosure includes a face plate having a plurality of drive slots into which the modular drives are inserted. The drives within each drive enclosure are normally user replaceable and hot swappable. Thus, one or more drive slots with the various drive enclosures of the data storage system may be open (i.e., unoccupied by a drive) allowing airflow dissipation from within the drive enclosure to the outside atmosphere. Further, if one or more drive slots are left open over a period of time, contaminants such as dirt, humidity, and the like from the outside environment may accumulate on the drive enclosure back plane connectors resulting in degraded connection of a drive that is inserted in the drive slot.

Consequently, it is desirable to provide a drive enclosure having drive slots which can be closed or covered when they are unoccupied by a drive. It would further be desirable that the drive slot be mechanically opened or uncovered by insertion of a drive into the drive slot so that no additional action is required from the user to install a drive within the drive enclosure.

### SUMMARY OF THE INVENTION

Accordingly, the present invention is directed to a drive enclosure for a modular data storage system having drive slots which include shutters for closing the drive slot when no drive is present in the slot. In exemplary embodiments, the shutter is mechanically opened by the drive as drive is received in the drive slot for allowing insertion of the drive within the drive slot and closes when the drive is removed from the drive slot. In this manner, the unused drive slots within a drive enclosure can remain closed in order to prevent dissipation of airflow, dirt, and contamination from or to the enclosure through the unused drive slots. Additionally, the shutters may identify free drive slots within a drive enclosure.

It is to be understood that both the foregoing general description and the following detailed description are exemplary and explanatory only and are not necessarily restrictive of the invention as claimed. The accompanying drawings, which are incorporated in and constitute a part of the specification, illustrate an embodiment of the invention and together with the general description, serve to explain the principles of the invention.

### BRIEF DESCRIPTION OF THE DRAWINGS

The numerous advantages of the present invention may be better understood by those skilled in the art by reference to the accompanying figures in which:

FIG. 1 is an isometric view illustrating a modular data storage system having a drive enclosure having mechanically operated drive slot shutters for closing unused drive slots in accordance with an exemplary embodiment of the present invention;

FIG. 2 is an isometric view illustrating the drive enclosure shown in FIG. 1, wherein a drive is removed from the drive enclosure;

FIG. 3 is front elevation view of the face plate of the drive enclosure shown in FIG. 2, illustrating mechanically operated drive slot shutters in accordance with a first exemplary embodiment of the present invention; FIG. 4 is a partial cross-sectional top plan view of the face plate shown in FIG. 3, illustrating operation of a drive slot shutter;

FIG. 5 is a front elevation view of the face plate of the drive enclosure shown in FIG. 2, illustrating mechanically operated drive slot shutters in accordance with a second exemplary embodiment of the present invention;

FIG. 6 is a partial cross-sectional edge elevation view of the face plate shown in FIG. 5, illustrating operation of the drive slot shutter;

FIG. 7 is a front elevation view of the face plate of the drive enclosure shown in FIG. 2, illustrating mechanically operated drive slot shutters in accordance with a third exemplary embodiment of the present invention; and

FIG. 8 is a partial cross-sectional edge elevation view of the face plate shown in FIG. 7, illustrating operation of the drive slot shutter;

### DETAILED DESCRIPTION OF THE INVENTION

Reference will now be made in detail to the presently preferred embodiments of the invention, examples of which are illustrated in the accompanying drawings.

FIG. 1 illustrates a modular data storage system 100 in accordance with an exemplary embodiment of the present invention. As shown, the modular data storage system 100 is comprised of a cabinet or rack 102 which supports a plurality of modular drive enclosures 104 each including a plurality of data storage drives 106 (e.g., Fibre Channel drives, serial ATA (Advanced Technology Attachment) drives, SCSI (Small Computer System Interface) drives, or the like) controlled by one or more controller modules 108. Each drive enclosure 104 may include a back plane connector assembly (not shown) for providing interconnection of the data storage drives 106 with the modular data storage system 100, redundant power supply systems for furnishing power to the data storage drives 106, an environmental control system for monitoring the status of components within the drive enclosure 104 and providing this information to one or more of the controller modules 108. Each controller module 108 may include redundant controllers running intelligent RAID (Redundant Array of Independent Disks) firmware, software, or the like, for providing connectivity of the data storage drives 106 (e.g., via 2 Gb/s Fibre Channel host or SAN (Storage Area Network) connectivity and support for Fibre Channel or serial ATA drives). The data storage drives 106 within each drive enclosure 104 are preferably user replaceable and hot swappable allowing easy replacement of drives 106 without interruption of operation of the modular data storage system 100.

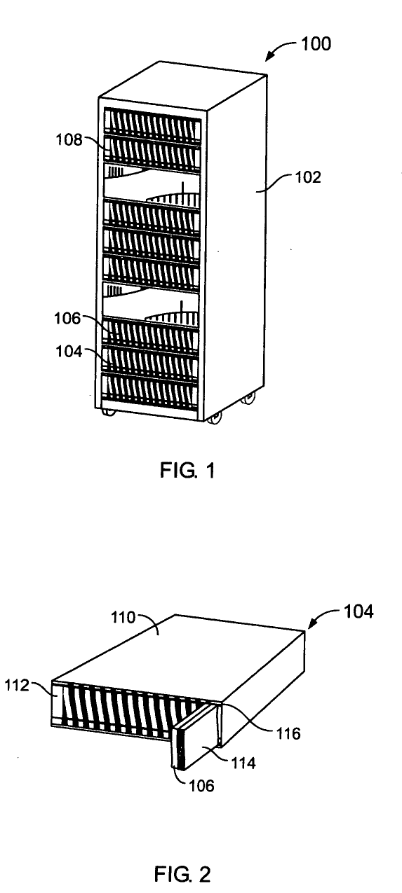

Turning now to FIG. 2, each modular drive enclosure 104 includes a generally box-shaped housing 110 sized to be received in the cabinet 102 of the modular data storage system 100. The housing 110 includes a face plate 112 having a plurality of drive slots 114 each sized to receive a data storage drive 106. In accordance with the present invention, each drive slot 114 includes a mechanically operated drive slot shutter 116 for closing the drive slot 114 when the drive slot 114 is open or unoccupied by a drive 106. In exemplary embodiments, the drive slot shutters 116 are implemented within the drive enclosure 104 as an integral part of the drive slots 114 provided within the face plate 112 the enclosure 102. The drive slot shutters 116, which have a width and form-factor similar to that of the data storage drives 106, close unused drive slots 114 to maintain ambient temperature within the drive enclosure 102 by preventing dissipation of cooling air from the enclosure 102 due to airflow through unused drive slots 114 to and from the environment surrounding the enclosure 102. Additionally, the drive slot shutters 116 may prevent contaminants such as dirt, moisture, and the like, from entering the interior of the drive enclosure 110 from the environment surrounding the drive enclosure 110 through open drive slots 112 were such contaminants may degrade the performance of components such as drive enclosure back plane, drive connectors, and the like. The drive slot shutters 116 may further function to identify free drive slots 114 (i.e., drive slots 114 which do not contain a data storage drive 106) within the drive enclosure 104.

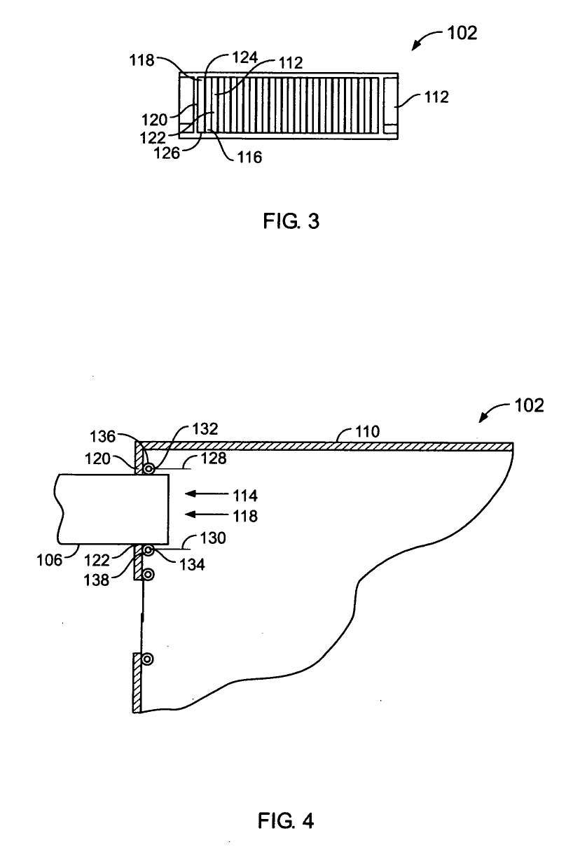

FIGS. 3 through 8 further illustrate embodiments of the face plate 112 of the drive enclosure 104 shown in FIG. 2. In the embodiments shown, each of the drive slots 114 comprises a generally rectangular aperture 118 sized for receiving a data storage drive 106, and includes a first (or left) edge 120, a second (or right) edge 122 opposite the first edge 120, a top edge 124, and a bottom edge 126 opposite the top edge 124.

In the embodiment illustrated in FIGS. 3 and 4, the mechanically operated drive slot shutter 116 of each drive slot 114 includes flaps 128 & 130 which together are sized to at least substantially cover the aperture 118 of the drive slot 114. As shown, a first one of the flaps 128 is hinged adjacent to the first edge 120 of the drive slot aperture 118 (at the top) via a first hinge assembly 132. Similarly, a second one of the flaps 130 is hinged adjacent to the second edge 122 of the drive slot aperture 118 via a second hinge assembly 134. The flaps 128 & 130 open inward (into the housing 110) upon insertion of the data storage drive 106 into the drive slot 114 through the drive slot aperture 118. Preferably, clearance is provided between the data storage drive 106 and the interior walls of the drive slot 114 to accommodate the flaps 128 & 130 when the flaps 128 & 130 are opened inward and the drive 106 is received in the drive slot 114. When a data storage drive 106 is not inserted in the drive slot 114, the flaps 128 & 130 are pivoted outward about hinges 132 & 134 by spring assemblies 136 & 138 located at the back of each flap 128 & 130 until the flaps 128 & 130 cover the drive slot aperture 118 closing the drive slot 114 (see FIG. 3). In exemplary embodiments, one of the flaps (e.g., flap 128) may have a width greater than the other (e.g., flap 130). In this manner, the first flap 128 may be permitted to overlap the second flap 130 in order to more fully eliminate any gap between the flaps 128 & 130 when the flaps 128 & 130 are closed and provide more complete sealing of the drive slot 114. Alternatively, each of the flaps 128 & 130 may be equal in width and may abut one another when closed to seal the drive slot 114.

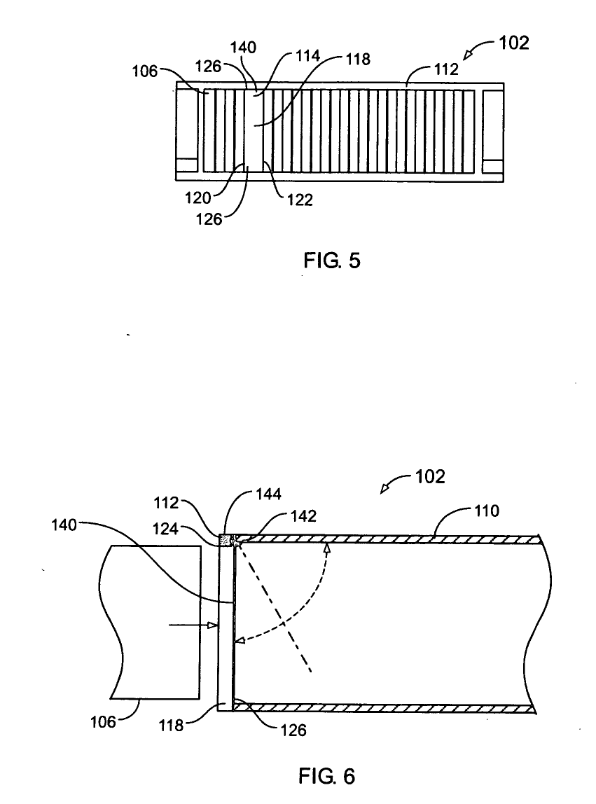

In the embodiment illustrated in FIGS. 5 and 6, the mechanically operated drive slot shutter 116 of each drive slot 114 includes a single flap 140 hinged adjacent to the top edge 112 of the drive slot 114 adjacent to the drive slot aperture 118 via a hinge 142. As shown, the flap 140 has a height and width sufficient to cover the aperture 118. As a data storage drive 106 is inserted into the drive slot 114 through aperture 118, the drive 106 pushes the flap 140 inward by causing the flap 140 to pivot upward (into the housing 110) about hinge 142, causing the drive slot 114 to be opened. While the data storage drive 106 is retained in the drive slot 114, the flap 140 is held inward above the drive 106 along the upper inward portion of the drive slot 114. When the drive is removed from the drive slot 114, the flap 140 pivots or drops down (due to the weight of the flap 140) to cover the aperture 118 and close the drive slot 114. A flap stopper 144 may be provided along the top front portion of the flap 140 along the top edge of the drive slot aperture 118 in order to maintain the position of the flap 140, to prevent the escape of air through the drive slot 114 and to reduce oscillatory (inward and outward) movement of the flap 140. Alternatively, a spring assembly may be provided to force the flap 140 to the closed position. Additionally, where a spring assembly is used to close the flap 140, it will be appreciated that the flap may be hinged along either of the first or second edges 120 & 122 or the bottom edge 126 of the drive slot aperture 118 without departing from the scope and intent of the present invention. In such embodiments, the flap stopper 144 is positioned along the front portion of the flap 140 adjacent to the edge of the drive slot aperture 118 to which the flap 140 is hinged.

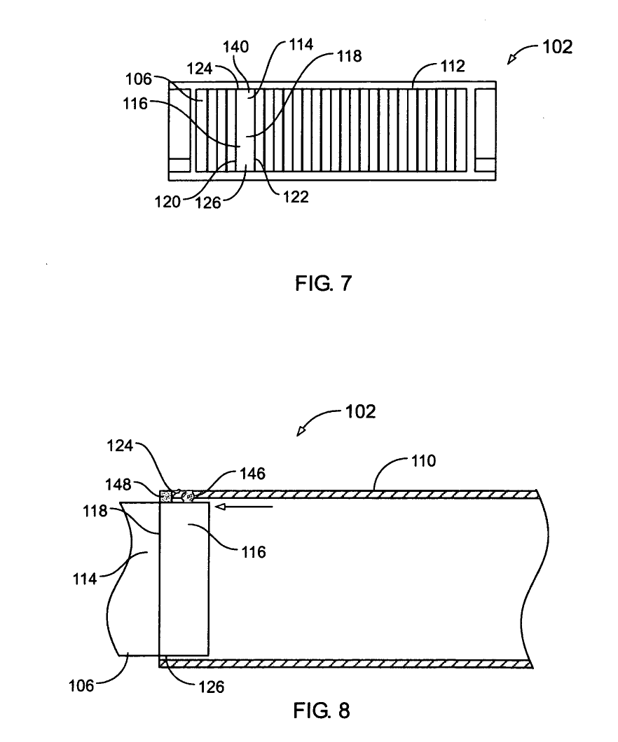

In the embodiment illustrated in FIGS. 7 and 8, the mechanically operated drive slot shutter 116 of each drive slot 114 comprises a coiled flap 146 that coils when a data storage drive 106 is received in the drive slot 114 and uncoils when the drive 106 is removed from the drive slot 114. In exemplary embodiments, the coiled flap 146 may comprise as telescopic leaf spring sized to cover the drive slot aperture 118. Like the embodiment shown in FIGS. 5 and 6, a flap stopper 148 may be provided along the top front portion of the flap 146 adjacent to the top edge 112 of the drive slot aperture 118 to maintain the position of the flap 146, to prevent the escape of air through the drive slot 114, and to reduce oscillatory (inward and outward) movement of the flap 146.

In the specific embodiments illustrated, a cabinet 102 supporting two controller modules 108 and eight drive enclosures 104 is illustrated. However, it will be appreciated that the cabinet 102 may support any technically feasible combination of controllers 108 and drive enclosures 104. Further, the face plate 112 of each drive enclosure 104 is illustrated as including fourteen rectangular drive slots 114. However, it is contemplated that the drive enclosures may support more or less than fourteen data storage drives 106 and that face plate 112 may be provided with a corresponding number of drive slots 114 (e.g., more or less than fourteen) without departing from the scope and intent of the present invention.

It is believed that the present invention and many of its attendant advantages will be understood by the foregoing description, and it will be apparent that various changes may be made in the form, construction and arrangement of the components thereof without departing from the scope and spirit of the invention or without sacrificing all of its material advantages. The form herein before described being merely an explanatory embodiment thereof, it is the intention of the following claims to encompass and include such changes.

What is claimed is:

1. A drive enclosure for a modular data storage system, comprising:
a face plate coupled to the housing assembly, the face plate including a drive slot formed therein for receiving a drive in the housing assembly;
a shutter for closing the drive slot when the drive slot is empty;
wherein the shutter opens as the drive is received in the drive slot for allowing insertion of the drive within the drive slot and closes when the drive is removed from the drive slot.

2. The drive enclosure as claimed in claim 1, wherein the drive slot includes a first edge and a second edge opposite the first edge, and the shutter comprises a first flap hinged adjacent to the first edge and a second flap hinged adjacent to the second edge, the first and second flaps opening inward into the drive slot when the drive is inserted into the drive slot.

3. The drive enclosure as claimed in claim 2, wherein the shutter further comprising a retention spring assembly for closing the first and second flaps when the drive is removed from the drive slot.

4. The drive enclosure as claimed in claim 1, wherein the drive slot includes a top edge and a bottom edge, and the shutter comprises a flap hinged adjacent to the top edge.

5. The drive enclosure as claimed in claim 4, further comprising a flap stopper adjacent to the top edge.

6. The drive enclosure as claimed in claim 1, wherein the drive slot includes a top edge and a bottom edge, and the shutter comprises a coiled flap, the coiled flap coiling when a drive is received in the drive slot and uncoiling when the drive is removed from the drive slot.

7. The drive enclosure as claimed in claim 6, further comprising a flap stopper adjacent to the top edge.

8. A modular data storage system, comprising: a cabinet assembly;
a drive enclosure received in the cabinet assembly, the drive enclosure including a face plate coupled to the housing assembly, the face plate including a plurality of drive slots formed therein, each drive slot for receiving drive in the housing assembly, each drive slot including a shutter for closing the drive slot when the drive slot is empty;
wherein the shutter opens as the drive is received in the drive slot for allowing insertion of the drive within the drive slot and closes when the drive is removed from the drive slot.

9. The modular data storage system as claimed in claim 8, wherein the drive slot includes a first edge and a second edge opposite the first edge, and the shutter comprises a first flap hinged adjacent to the first edge and a second flap hinged adjacent to the second edge, the first and second flaps opening inward when the drive is inserted into the drive slot.

10. The modular data storage system as claimed in claim 9, further comprising a retention spring assembly for closing the first and second flaps when the drive is removed from the drive slot.

11. The modular data storage system as claimed in claim 8, wherein the drive slot includes a top edge and a bottom edge, and the shutter comprises a flap hinged adjacent to the top edge.

12. The modular data storage system as claimed in claim 11, further comprising a flap stopper adjacent to the top edge.

13. The modular data storage system as claimed in claim 8, wherein the drive slot includes a top edge and a bottom edge, and the shutter comprises a coiled flap, the coiled flap coiling when a drive is received in the drive slot and uncoiling when the drive is removed from the drive slot.

14. The modular data storage system as claimed in claim 13, further comprising a flap stopper adjacent to the top edge.

15. A drive enclosure for a modular data storage system, comprising:
a face plate coupled to the housing assembly, the face plate including a drive slot formed therein for receiving a drive in the housing assembly;
means for closing the drive slot when the drive slot is empty;
wherein the closing means opens as the drive is received in the drive slot for allowing insertion of the drive within the drive slot and closes when the drive is removed from the drive slot.

16. The drive enclosure as claimed in claim 15, wherein the drive slot includes a first edge and a second edge opposite the first edge, and the closing means comprises a first flap hinged adjacent to the first edge and a second flap hinged adjacent to the second edge, the first and second flaps opening inward when the drive is inserted into the drive slot.

17. The drive enclosure as claimed in claim 16, wherein the closing means further comprises a retention spring assembly for closing the first and second flaps when the drive is removed from the drive slot.

18. The drive enclosure as claimed in claim 15, wherein the drive slot includes a top edge and a bottom edge, and the closing means comprises a flap hinged adjacent to the top edge.

19. The drive enclosure as claimed in claim 15, wherein the drive slot includes a top edge and a bottom edge, and the closing means comprises a coiled flap, the coiled flap coiling when a drive is received in the drive slot and uncoiling when the drive is removed from the drive slot.

20. The drive enclosure as claimed in claim 15, further comprising a means for sealing a gap between the closing means and the drive slot adjacent to the top edge.
